(19) United States
(12) Patent Application Publication
(10) Pub. No.: US 2024/0074131 A1
(43) Pub. Date: Feb. 29, 2024

(54) MOUNTING WORK SYSTEM AND METHOD FOR EXCHANGING TAPE FEEDER

(71) Applicant: FUJI CORPORATION, Chiryu (JP)

(72) Inventors: Mizuho NOZAWA, Kota-cho, Nukata-gun (JP); Hidetoshi KAWAI, Anjo-shi (JP); Masataka IWASAKI, Anjo-shi (JP)

(73) Assignee: FUJI CORPORATION, Chiryu (JP)

(21) Appl. No.: 18/259,891

(22) PCT Filed: Jan. 19, 2021
(86) PCT No.: PCT/JP2021/001679

§ 371 Date: Jun. 29, 2023

(51) Int. Cl. H05K 13/04; H05K 13/02

(52) U.S. Cl. CPC H05K 13/0419; H05K 13/021

(57) ABSTRACT

A mounting work system includes at least one feeder automatic exchange work machine configured to mount a component, which is supplied by a tape feeder mounted on a mounting stand, on a board conveyed by a conveyance device, the tape feeder mounted on the mounting stand being configured to be automatically exchanged by an operation of a tape feeder exchange device, at least one feeder manual exchange work machine configured to mount a component, which is supplied by a tape feeder mounted on a mounting stand, on the board conveyed by a conveyance device, the tape feeder mounted on the mounting stand being configured to be manually exchanged by an operator, and a housing formed with a housing space for housing at least one tape feeder, arranged in a conveyance direction of the conveyance devices, and disposed adjacent to the at least one feeder automatic exchange work machine.

### TECHNICAL FIELD

The present disclosure relates to a mounting work system including a work machine in which a tape feeder is automatically exchanged by an operation of a tape feeder exchange device, and a method for exchanging a tape feeder.

### BACKGROUND ART

Patent Literatures below describes a technique of mounting a component supplied by a tape feeder to a board.

### PATENT LITERATURE

Patent Literature 1: JP-A-2019-075466
Patent Literature 2: JP-A-2020-014021

### BRIEF SUMMARY

### Technical Problem

The present specification is to appropriately exchange a tape feeder.

### Solution to Problem

In order to solve the above-described problems, the present specification discloses a mounting work system including at least one feeder automatic exchange work machine configured to mount a component, which is supplied by a tape feeder mounted on a mounting stand, on a board conveyed by a conveyance device, the tape feeder mounted on the mounting stand being configured to be automatically exchanged by an operation of a tape feeder exchange device, at least one feeder manual exchange work machine configured to mount a component, which is supplied by a tape feeder mounted on a mounting stand, on the board conveyed by a conveyance device, the tape feeder mounted on the mounting stand being configured to be manually exchanged by an operator, and a housing formed with a housing space for housing at least one tape feeder, arranged in a conveyance direction of the conveyance devices, and disposed adjacent to the at least one feeder automatic exchange work machine.

### Advantageous Effects

In mounting work system of the present specification, the housing for housing the tape feeder is disposed adjacent to the work machine in which the tape feeder is automatically exchanged by the operation of the tape feeder exchange device. In a method for exchanging a tape feeder of the present specification, multiple tape feeders are collectively exchanged by using an exchange mechanism. As a result, the tape feeder can be appropriately exchanged.

### BRIEF DESCRIPTION OF DRAWINGS

FIG. 1 is a perspective view illustrating a board work system.

FIG. 2 is a perspective view illustrating an automatic exchange mounting device and a feeder exchange device.

FIG. 3 is a perspective view illustrating a tape feeder.

FIG. 4 is a schematic diagram illustrating exchange work of the tape feeder.

FIG. 5 is a perspective view illustrating a housing rack.

FIG. 6 is a block diagram illustrating a control device.

### DESCRIPTION OF EMBODIMENTS

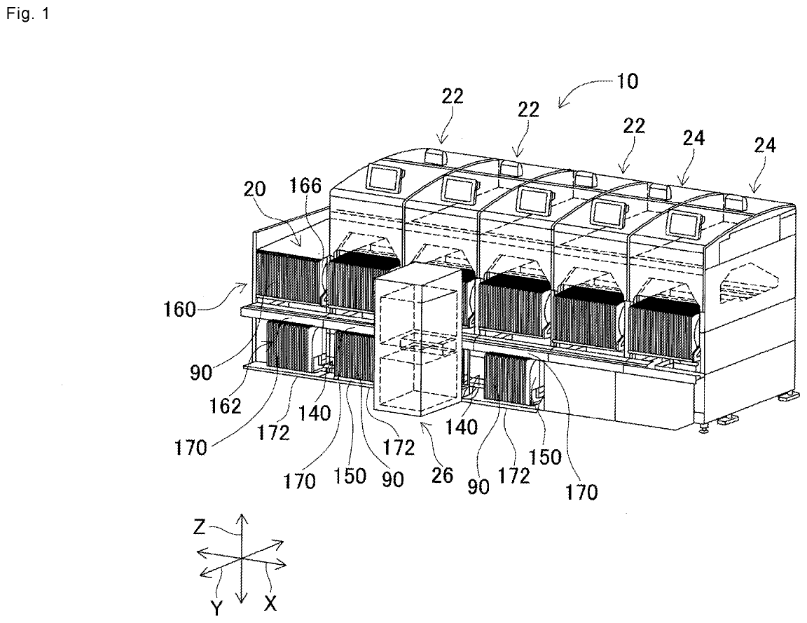

FIG. 1 illustrates board work system 10. Board work system 10 illustrated in FIG. 1 is a system for mounting an electronic component on a circuit board. Board work system 10 includes one feeder housing 20, three automatic exchange mounting devices 22, two manual exchange mounting devices 24, and one feeder exchange device 26. One feeder housing 20, three automatic exchange mounting devices 22, and two manual exchange mounting devices 24 are disposed in a row in a state in which one feeder housing 20, three automatic exchange mounting devices 22, and two manual exchange mounting devices 24 are adjacent to each other in this order. Feeder exchange device 26 is disposed on a front side of automatic exchange mounting device 22 (front side in FIG. 1). In the following description, an arranging direction of feeder housing 20, automatic exchange mounting device 22, and manual exchange mounting device 24 is referred to as an X-direction, and a horizontal direction perpendicular to the X-direction is referred to as a Y-direction, and a direction orthogonal to the X-direction and the Y-direction is referred to as a Z-direction. In the X-direction, a side on which feeder housing 20 is disposed is referred to as an upstream side, and a side on which manual exchange mounting device 24 is disposed is referred to as a downstream side.

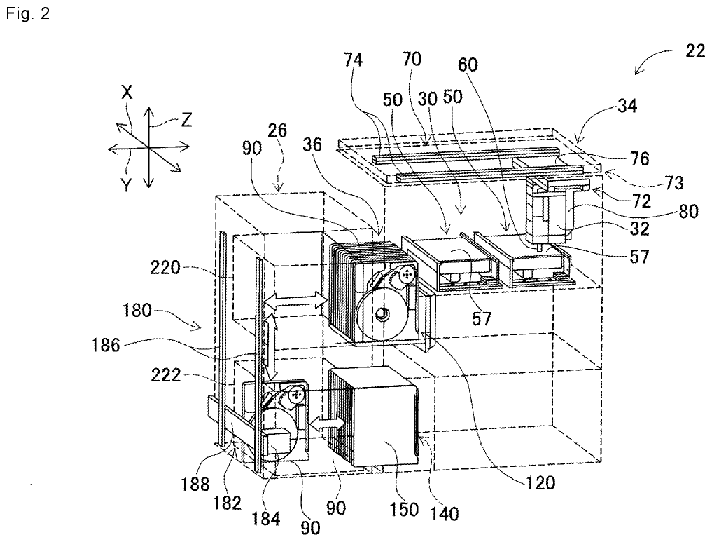

Three automatic exchange mounting devices 22 have substantially the same configuration as each other, and each of three automatic exchange mounting devices 22 includes conveyance device 30, mounting head 32, mounting head moving device (hereinafter, referred to as a “moving device” in some cases) 34, and supply device 36, as illustrated in FIG. 2.

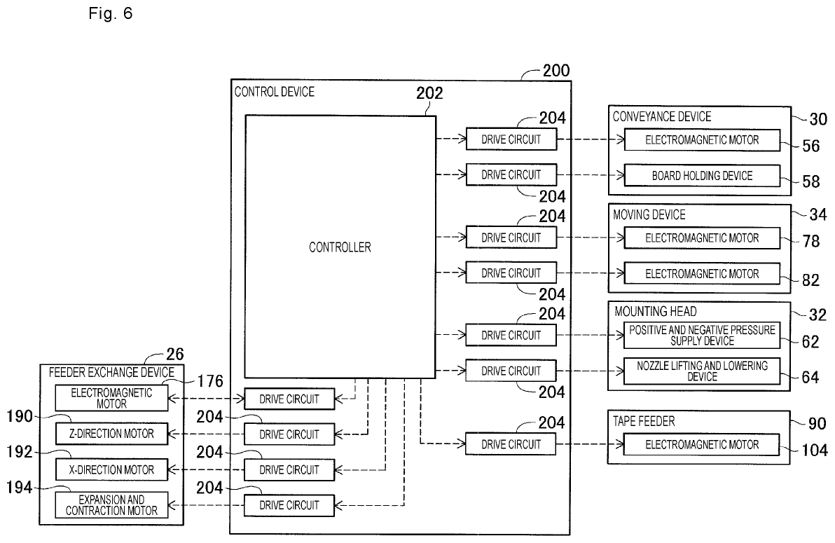

Conveyance device 30 includes two conveyor devices 50. Two conveyor devices 50 are disposed on base 52 to extend parallel to each other and in the X-direction. Each of two conveyor devices 50 conveys circuit board 57 supported by each conveyor device 50 in the X-direction by electromagnetic motor 56 (see FIG. 6). In addition, each conveyor device 50 has board holding device 58 (see FIG. 6), and holds circuit board 57 at a predetermined position in a fixed manner.

Mounting head 32 mounts the electronic component on circuit board 57. Specifically, mounting head 32 has suction nozzle 60 provided on a lower end surface thereof. Suction nozzle 60 communicates with positive and negative pressure supply device 62 (see FIG. 6) via negative pressure air and positive pressure air passages. Suction nozzle 60 picks up and holds the electronic component by using a negative pressure, and separates the held electronic component by using a positive pressure. In addition, mounting head 32 includes nozzle lifting and lowering device 64 (see FIG. 6) that lifts and lowers suction nozzle 60. Nozzle lifting and lowering device 64 changes a position of mounting head 32 in an up-down direction of the electronic component to be held. It should be noted that suction nozzle 60 is detachable from mounting head 32, and can be changed to a suction nozzle having a different size.

Moving device 34 is a device that moves mounting head 32 to any position on base 52. Specifically, moving device 34 includes X-direction slide mechanism 70 and Y-direction slide mechanism 72. Y-direction slide mechanism 72 is disposed on beam 73 suspended on base 52 and has pair of Y-direction guide rails 74. Pair of Y-direction guide rails 74 is disposed to extend in the Y-direction. Meanwhile, X-direction slide mechanism 70 has X-direction guide rail 76, and X-direction guide rail 76 is held by pair of Y-direction guide rails 74 to extend in the X-direction. Y-direction slide mechanism 72 includes electromagnetic motor 78 (see FIG. 6), and X-direction guide rail 76 is moved to any position in the Y-direction by the driving of electromagnetic motor 78. X-direction guide rail 76 holds slider 80 to be movable along an axis of X-direction guide rail 76. X-direction slide mechanism 70 includes electromagnetic motor 82 (see FIG. 6), and slider 80 is moved to any position in the X-direction by the driving of electromagnetic motor 82. Mounting head 32 is mounted on slider 80. With such a configuration, mounting head 32 is moved to any position on base 52 by moving device 34. Mounting head 32 is detachable from slider 80 by a one-touch operation. As a result, it is possible to change a work head to a different type of work head such as a dispenser head.

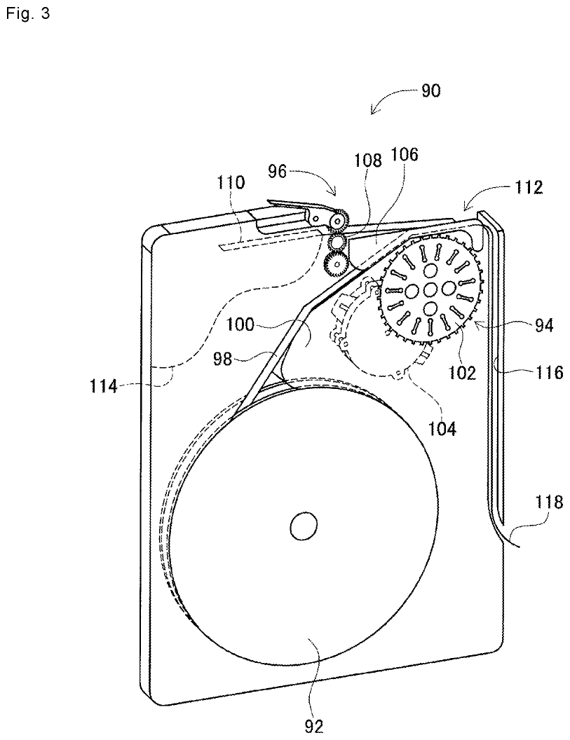

Supply device 36 is disposed at an end portion on a front side of base 52, and includes multiple tape feeders 90. As illustrated in FIG. 3, each tape feeder 90 includes reel 92, feed-out device 94, and peeling device 96, and supplies the electronic component at an end portion of an upper surface. Specifically, taped component 98 is wound on reel 92, and taped component 98 is pulled out from reel 92 onto tape guide 100. Taped component 98 is a component in which the electronic component is taped, and feed holes (not illustrated) are formed at a predetermined pitch. Sprocket 102 of feed-out device 94 meshes with the feed hole. Sprocket 102 is rotated by electromagnetic motor 104. With such a configuration, taped component 98 is fed out toward a supply position.

In addition, peeling device 96 includes film peeling mechanism 106 and gear mechanism 108. Film peeling mechanism 106 is a mechanism for peeling top film 110 from taped component 98, and is disposed in front of opening 112 formed in an upper surface end portion of tape feeder 90. Gear mechanism 108 is a mechanism for pulling top film 110 peeled from taped component 98 into film collection section 114. With such a configuration, top film 110 is peeled from taped component 98, so that the electronic component housed in taped component 98 is exposed in opening 112, and the exposed electronic component is picked up and held by suction nozzle 60 of mounting head 32. That is, opening 112 is an electronic component supply position of tape feeder 90. Tape guide passage 116 is formed on a side surface of opening 112 in a feed-out direction of taped component 98 to be directed downward. Waste tape 118 from which the electronic component is extracted from taped component 98 is discharged through tape guide passage 116.

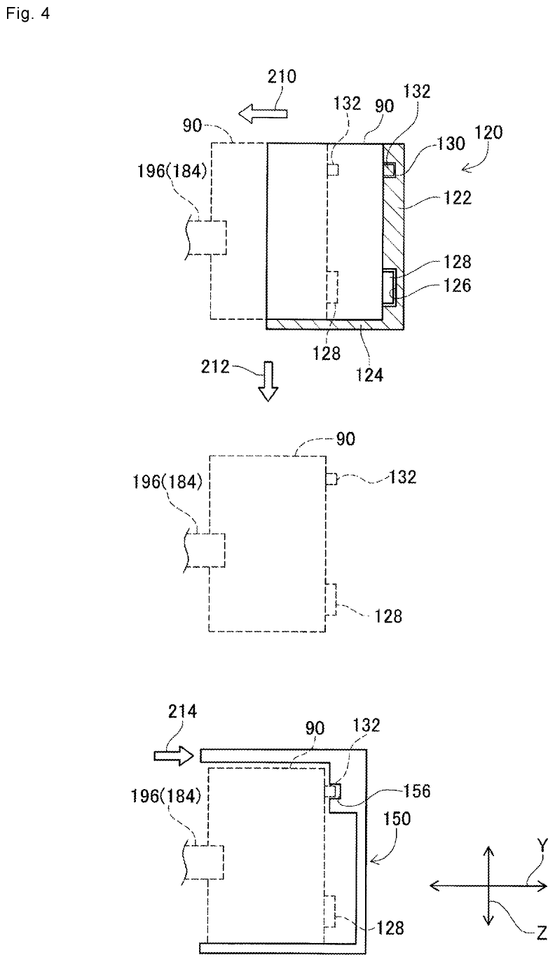

As illustrated in FIG. 2, tape feeder 90 is detachable from tape feeder holding stand 120 provided at the end portion on the front side of base 52 in a fixed manner. As illustrated in FIG. 4, tape feeder holding stand 120 includes upright surface 122 that is upright in a vertical direction with respect to base 52, and protruding surface 124 protruding from a lower end of upright surface 122. Connector connection section 126 is provided on upright surface 122. Meanwhile, connector 128 is provided on a side surface of tape feeder 90. Connector 128 of tape feeder 90 is connected to connector connection section 126 of upright surface 122, so that a bottom surface of tape feeder 90 is supported by protruding surface 124. As a result, tape feeder 90 is electrically connected to tape feeder holding stand 120. In addition, insertion hole 130 is provided in upright surface 122. Meanwhile, pin 132 is provided on the side surface of tape feeder 90. Then, pin 132 of tape feeder 90 is connected to insertion hole 130 of upright surface 122, so that tape feeder 90 is positioned in tape feeder holding stand 120.

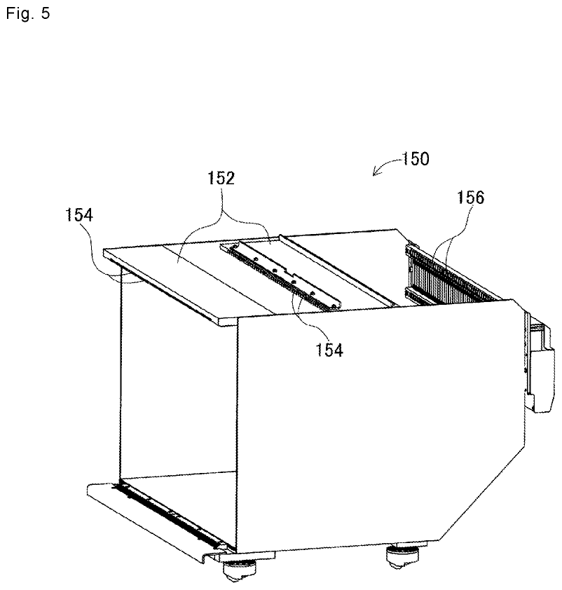

As illustrated in FIG. 2, housing space 140 is formed below tape feeder holding stand 120. Housing space 140 is a space for housing multiple tape feeders 90 by utilizing an entire width direction of a free space below tape feeder holding stand 120, that is, the X-direction. Housing rack 150 illustrated in FIG. 5 is positioned and mounted in housing space 140 in a detachable manner by the one-touch operation of an operator.

Housing rack 150 has a box shape in which a front surface is opened. A height dimension of the interior of housing rack 150 having the box shape is slightly larger than a height dimension of tape feeder 90, and a depth dimension of the interior of housing rack 150 is slightly larger than a depth dimension of tape feeder 90. A width dimension of the interior of housing rack 150 is larger than a width dimension of tape feeder 90 by N times (for example, 30 times). N tape feeders 90 can be housed in an arranged manner in housing rack 150 having such a shape. Multiple (N) rails 154 are formed on a lower surface of top plate 152 of housing rack 150 to extend in a front-rear direction. In addition, N insertion holes 156 are formed in an inside of a rear surface of housing rack 150 in an arranged manner in a width direction of housing rack 150. Therefore, an upper end of tape feeder 90 is fitted into rail 154, and pin 132 of tape feeder 90 is inserted into insertion hole 156, so that tape feeder 90 is positioned in housing rack 150.

In addition, an outer dimension of housing rack 150 is slightly smaller than an inner dimension of housing space 140. Therefore, housing rack 150 can be housed in housing space 140, that is, below tape feeder holding stand 120. As a result, housing rack 150 in which multiple tape feeders 90 are housed is housed in housing space 140 as illustrated in FIG. 1, so that multiple tape feeders 90 can be stored by utilizing the free space below automatic exchange mounting device 22.

In addition, two manual exchange mounting devices 24 have substantially the same configuration as each other, and each of two manual exchange mounting devices 24 has substantially the same configuration as automatic exchange mounting device 22 except for housing space 140. That is, as illustrated in FIG. 1, the configuration is substantially the same as that of automatic exchange mounting device 22 except that housing space 140 is not formed below manual exchange mounting device 24 and tape feeder 90 cannot be stored. Therefore, the detailed description of manual exchange mounting device 24 will be omitted, and the same reference numerals as those of the elements of automatic exchange mounting device 22 will be used for the elements of manual exchange mounting device 24, that is, the conveyance device, the mounting head, the moving device, the supply device, and the like.

Feeder housing 20 has a two-stage shelf shape, upper housing space 160 is formed in an upper stage of the two-stage shelf, and lower housing space 162 is formed in a lower stage. Width dimensions and depth dimensions of the interior of upper housing space 160 and lower housing space 162 are the same, but a height dimension of the interior of upper housing space 160 is slightly larger than a height dimension of lower housing space 162. An inner dimension of lower housing space 162 is the same as the inner dimension of housing space 140 of automatic exchange mounting device 22. Therefore, it is possible to house housing rack 150 in lower housing space 162, and it is possible to store multiple tape feeders 90 in the lower stage of feeder housing 20 by housing, in lower housing space 162, housing rack 150 in which multiple tape feeders 90 are housed.

In addition, housing rack (referred to as an upper stage housing rack) 166 having substantially the same structure as housing rack 150 except for the height dimensions is also prepared, and N tape feeders 90 can be housed in upper stage housing rack 166 in the same manner as housing rack 150. The height dimension of upper stage housing rack 166 is slightly smaller than the height dimension of upper housing space 160. Therefore, it is possible to house upper stage housing rack 166 in upper housing space 160, and it is possible to store multiple tape feeders 90 in the upper stage of feeder housing 20 by housing upper stage housing rack 166 in which multiple tape feeders 90 are housed in upper housing space 160.

In addition, feeder exchange device 26 performs exchange work of tape feeder 90 with respect to each of three automatic exchange mounting devices 22 and feeder housing 20. Specifically, upper guide rail 170 and lower guide rail 172 are disposed on the front surfaces of three automatic exchange mounting devices 22 and feeder housing 20 to extend in the X-direction. It should be noted that upper guide rails 170 disposed on the front surfaces of automatic exchange mounting device 22 and feeder housing 20 are connected to form a single rail. In addition, lower guide rails 172 disposed on the front surfaces of automatic exchange mounting device 22 and feeder housing 20 are also connected to form a single rail. Feeder exchange device 26 is held by upper guide rail 170 and lower guide rail 172 to be slidable in the X-direction, and is moved to any position in the X-direction by the driving of electromagnetic motor 176 (see FIG. 6).

As illustrated in FIG. 2, feeder exchange device 26 includes lifting and lowering device 180, horizontal moving device 182, and clamp mechanism 184. Lifting and lowering device 180 has pair of Z-direction guide rails 186, and pair of Z-direction guide rails 186 are disposed on the front side of tape feeder holding stand 120 and housing space 140 of automatic exchange mounting device 22 to extend in the Z-direction. In addition, horizontal moving device 182 has X-direction guide rail 188, and X-direction guide rail 188 is held by pair of Z-direction guide rails 186 to extend in the X-direction. X-direction guide rail 168 is moved to any position in the Z-direction by the driving of Z-direction motor 190 (see FIG. 6). In addition, X-direction guide rail 168 holds clamp mechanism 184 to be movable along an axis of X-direction guide rail 168. Clamp mechanism 184 is moved to any position in the X-direction by the driving of X-direction motor 192 (see FIG. 6). In addition, clamp mechanism 184 can expand and contract in the Y-direction, and expands and contracts in the Y-direction by the driving of expansion and contraction motor (see FIG. 6) 194. Clamp section 196 that clamps tape feeder 90 (see FIG. 4) is provided at a distal end portion of clamp mechanism 184. With such a configuration, feeder exchange device 26 automatically exchanges tape feeder 90 between tape feeder holding stand 120 and housing space 140, as will be described in detail later.

In addition, as illustrated in FIG. 6, board work system 10 includes control device 200. Control device 200 includes controller 202 and multiple drive circuits 204. Multiple drive circuits 204 are connected to electromagnetic motors 56, 78, 82, and 104 of automatic exchange mounting device 22 and manual exchange mounting device 24, board holding device 58, positive and negative pressure supply device 62, nozzle lifting and lowering device 64, and electromagnetic motors 176, Z-direction motor 190, X-direction motor 192, and expansion and contraction motor 194 of feeder exchange device 26. Controller 202 includes CPU, ROM, RAM, and the like, is mainly implemented by a computer, and is connected to multiple drive circuits 204. As a result, the operations of conveyance device 30, moving device 34 feeder exchange device 26, and the like are controlled by controller 202.

With the above-described configuration, in board work system 10, circuit board 57 is conveyed by conveyance device 30 into three automatic exchange mounting devices 22 and two manual exchange mounting devices 24, and the electronic components are mounted on circuit board 57 by automatic exchange mounting device 22 and manual exchange mounting device 24. It should be noted that since the mounting work of the electronic component in automatic exchange mounting device 22 and the mounting work of the electronic component in manual exchange mounting device 24 are the same, automatic exchange mounting device 22 and manual exchange mounting device 24 will be collectively referred to as mounting devices 22 and 24 in the description of the mounting work.

Specifically, first, circuit board 57 is carried into the mounting device disposed at the uppermost stream of five mounting devices 22 and 24. In the mounting device, circuit board 57 is conveyed to a work position by a command of controller 202, and is held by board holding device 58 at the work position in a fixed manner. In addition, tape feeder 90 mounted on tape feeder holding stand 120 feeds out the taped component by the command of controller 202, and supplies the electronic component at the supply position. Then, mounting head 32 is moved to an upper side of the supply position of the electronic component by the command of controller 202, and picks up and holds the electronic component by suction nozzle 60. Subsequently, mounting head 32 is moved to an upper side of circuit board 57, and mounts the held electronic component on the circuit board. In a case where the mounting work of the electronic component on the circuit board is terminated, the circuit board is conveyed toward the downstream side and is carried into the mounting device disposed on the downstream side. The above-described mounting work is subsequently performed by each mounting device, so that the circuit board on which the electronic components are mounted is manufactured.

In this manner, mounting devices 22 and 24 are configured to pick up and hold the electronic components supplied by tape feeder 90 by suction nozzle 60 of mounting head 32, and to mount the picked up and held electronic components on the circuit board. In mounting devices 22 and 24 configured as described above, tape feeder 90 mounted on tape feeder holding stand 120 is exchanged with new tape feeder 90 in order to handle a shortage of the electronic components or the like.

In manual exchange mounting device 24, the operator detaches tape feeder 90 mounted on tape feeder holding stand 120, and mounts new tape feeder 90 in place of detached tape feeder 90. In other words, in manual exchange mounting device 24, the exchange work of tape feeder 90 is performed manually. On the other hand, in automatic exchange mounting device 22, the exchange work of tape feeder 90 is automatically performed.

Specifically, in a case where the number of electronic components of tape feeder 90 mounted on tape feeder holding stand 120 of automatic exchange mounting device 22 is equal to or smaller than a predetermined number, electromagnetic motor 176 is driven by the command of controller 202, so that feeder exchange device 26 is moved to the front side of automatic exchange mounting device 22. Next, Z-direction motor 190 and X-direction motor 192 of lifting and lowering device 180 and horizontal moving device 182 are driven by the command of controller 202, so that clamp mechanism 184 is moved to a position facing the tape feeder (hereinafter, referred to as a “used feeder 90a”) in which the number of electronic components is equal to or smaller than the predetermined number. Then, expansion and contraction motor 194 is driven by the command of controller 202, and clamp mechanism 184 expands to approach used feeder 90a and clamps used feeder 90a by clamp section 196. In a case where used feeder 90a is clamped by clamp section 196, expansion and contraction motor 194 is driven by the command of controller 202, so that clamp mechanism 184 contracts. As a result, used feeder 90a is pulled out in a direction of arrow 210 and detached from tape feeder holding stand 120, as illustrated in FIG. 4. In this case, used feeder 90a detached from tape feeder holding stand 120 is pulled into upper transfer section 220 of feeder exchange device 26 (see FIG. 2).

Next, Z-direction motor 190 of lifting and lowering device 180 is driven by the command of controller 202, so that clamp mechanism 184 is moved in a direction of arrow 212 (downward direction). As a result, used feeder 90a clamped by clamp section 196 is moved from upper transfer section 220 to lower transfer section 222 (see FIG. 2) in feeder exchange device 26. Lower transfer section 222 is formed at a position facing housing space 140 of automatic exchange mounting device 22, and clamp mechanism 184 is moved to lower transfer section 222 to face housing rack 150 housed in housing space 140.

Then, X-direction motor 192 of horizontal moving device 182 is driven by the command of controller 202, so that clamp mechanism 184 is moved in the X-direction. In this case, the driving of X-direction motor 192 is controlled so that used feeder 90a clamped by clamp section 196 is moved to a position facing a free slot in housing rack 150 in which tape feeder 90 is not housed. Then, expansion and contraction motor 194 is driven by the command of controller 202, so that clamp mechanism 184 expands. As a result, used feeder 90a is pushed in a direction of arrow 214 and is housed in the free slot of housing rack 150. In a case where used feeder 90a is housed in the slot, clamp mechanism 184 releases the clamp of used feeder 90a by the command of controller 202, and contracts.

Subsequently, in a case where the tape feeder scheduled to be mounted on tape feeder holding stand 120 (hereinafter, referred to as a “mounting-scheduled feeder 90b”) in place of used feeder 90a is housed in housing rack 150 of housing space 140, X-direction motor 192 of horizontal moving device 182 is driven by the command of controller 202, so that clamp mechanism 184 is moved to the front side of mounting-scheduled feeder 90b. Expansion and contraction motor 194 is driven by the command of controller 202 and clamp mechanism 184 expands, so that mounting-scheduled feeder 90b is clamped by clamp section 196.

Next, in a case where mounting-scheduled feeder 90b is clamped by clamp section 196, expansion and contraction motor 194 is driven by the command of controller 202 and clamp mechanism 184 contracts, so that mounting-scheduled feeder 90b is pulled out from housing rack 150. In this case, mounting-scheduled feeder 90b pulled out from housing rack 150 is pulled into lower transfer section 222 of feeder exchange device 26. Subsequently, Z-direction motor 190 of lifting and lowering device 180 is driven by the command of controller 202, and clamp mechanism 184 is moved upward. As a result, mounting-scheduled feeder 90b clamped by clamp section 196 is moved from lower transfer section 222 to upper transfer section 220 in feeder exchange device 26. Then, X-direction motor 192 of horizontal moving device 182 is driven by the command of controller 202, so that clamp mechanism 184 is moved in the X-direction. In this case, the driving of X-direction motor 192 is controlled so that mounting-scheduled feeder 90b clamped by clamp section 196 is moved to the front side of tape feeder holding stand 120 on which used feeder 90a is mounted.

Subsequently, expansion and contraction motor 194 is driven by the command of controller 202, and clamp mechanism 184 expands to approach tape feeder holding stand 120, so that mounting-scheduled feeder 90b is mounted on tape feeder holding stand 120. Then, in a case where mounting-scheduled feeder 90b is mounted on tape feeder holding stand 120, clamp mechanism 184 releases the clamping of mounting-scheduled feeder 90b by the command of controller 202, and contracts. By the above-described series of operations of feeder exchange device 26, the exchange work between used feeder 90a and mounting-scheduled feeder 90b is automatically performed.

In a case where mounting-scheduled feeder 90b is housed in feeder housing 20, after used feeder 90a is housed in housing rack 150 of housing space 140, electromagnetic motor 176 is driven by the command of controller 202, and feeder exchange device 26 is moved to the front side of feeder housing 20. Then, Z-direction motor 190 and X-direction motor 192 of lifting and lowering device 180 and horizontal moving device 182 are driven by the command of controller 202, so that clamp mechanism 184 is moved to the front side of mounting-scheduled feeder 90b. Then, expansion and contraction motor 194 is driven by the command of controller 202, and clamp mechanism 184 expands to approach mounting-scheduled feeder 90b and clamps mounting-scheduled feeder 90b by clamp section 196. Since the method after mounting-scheduled feeder 90b is clamped by clamp section 196 is the same as the method described above, the description thereof will be omitted.

Incidentally, in the above-described example, board work system 10 is an example of a mounting work system. Feeder housing 20 is an example of a housing. Automatic exchange mounting device 22 is an example of a mounting work machine and a feeder automatic exchange work machine. Manual exchange mounting device 24 is an example of a mounting work machine and a feeder manual exchange work machine. Feeder exchange device 26 is an example of a tape feeder exchange device. Conveyance device 30 is an example of a conveyance device. Tape feeder 90 is an example of a tape feeder. Tape feeder holding stand 120 is an example of a mounting stand. Housing space 140 is an example of a housing space. Housing rack 150 is an example of an exchange mechanism. Upper housing space 160 and lower housing space 162 are examples of a housing space.

The present embodiment, which has been described heretofore, provides the following effects.

In board work system 10, feeder housing 20 is disposed adjacent to three automatic exchange mounting devices 22. Therefore, for example, in a case where mounting-scheduled feeder 90b is housed in feeder housing 20, a movement distance of automatic exchange mounting device 22 can be reduced. As a result, it is possible to shorten the time required for the exchange work of tape feeder 90.

In board work system 10, two manual exchange mounting devices 24 are disposed adjacent to three automatic exchange mounting devices 22 on a side opposite to feeder housing 20. In other words, in board work system 10, feeder housing 20, one group of automatic exchange mounting devices 22 and one group of manual exchange mounting devices 24 are disposed in a state in which feeder housing 20, one group of automatic exchange mounting devices 22, and one group of manual exchange mounting devices 24 are arranged in this order. As a result, the mounting work can be performed by a first one of automatic exchange mounting device 22 and manual exchange mounting device 24 with respect to the circuit board on which the mounting work in a second one of automatic exchange mounting device 22 and manual exchange mounting device 24 is completed.

In board work system 10, housing space 140 is formed below automatic exchange mounting device 22, and tape feeder 90 is housed in housing space 140. Therefore, for example, in a case where mounting-scheduled feeder 90b is housed in housing space 140, tape feeder 90 is automatically exchanged between tape feeder holding stand 120 and housing space 140 without moving feeder exchange device 26. As a result, it is possible to shorten the time required for the exchange work of tape feeder 90. In addition, it is possible to store tape feeder 90 also in automatic exchange mounting device 22 in addition to feeder housing 20, and it is possible to store a large number of tape feeders 90 in board work system 10. Furthermore, housing space 140 houses multiple tape feeders 90 by utilizing the entire width direction of the free space below tape feeder holding stand 120. As a result, it is possible to store a large number of tape feeders 90. As a result, the number of tape feeders 90 stored in places other than board work system 10 can be reduced, so that the storage area of tape feeder 90 can be reduced.

In board work system 10, multiple tape feeders 90 can be collectively exchanged in housing space 140 of automatic exchange mounting device 22 and lower housing space 162 of feeder housing 20 by using housing rack 150. In addition, multiple tape feeders 90 can be collectively exchanged in upper housing space 160 of feeder housing 20 by using upper stage housing rack 166. In other words, the operator can collectively exchange multiple tape feeders 90 by merely housing multiple tape feeders 90 in housing racks 150 and 166, and inserting and taking housing racks 150 and 166 into and from housing spaces 140, 160, and 162. As a result, it is possible to reduce the labor of the operator.

In board work system 10, two stages of housing spaces, that is, upper housing space 160 and lower housing space 162 are formed in feeder housing 20. As a result, it is possible to store a large number of tape feeders 90 in feeder housing 20.

The present disclosure is not limited to the above-described example, but can be performed in various forms in which various changes and improvements are made based on the knowledge of those skilled in the art. Specifically, for example, in the above-described example, housing space 140 is formed in automatic exchange mounting device 22, but the housing space may be formed in manual exchange mounting device 24. As described above, the housing space is also formed in manual exchange mounting device 24, so that a larger number of tape feeders 90 can be stored.

In the above-described example, multiple tape feeders 90 are collectively exchanged by utilizing housing rack 150, but multiple tape feeders 90 may be collectively exchanged by utilizing other mechanisms. For example, a structure is adopted in which a mounting section on which multiple tape feeders 90 can be mounted is formed on a carriage, and the mounting section can be inserted into housing space 140. Then, multiple tape feeders 90 may be mounted on the mounting section, and the mounting section may be inserted into free housing space 140, so that multiple tape feeders 90 are collectively mounted in housing space 140. In addition, a free mounting section may be inserted into housing space 140 in which multiple tape feeders 90 are housed, so that multiple tape feeders 90 may be collectively extracted from housing space 140.

In the above-described example, the operator manually houses housing rack 150 or the like in housing space 140 or the like, but housing rack 150 or the like may be automatically housed in housing space 140 or the like by a housing device or the like.

In the above-described example, multiple tape feeders 90 are collectively exchanged by utilizing housing rack 150 in board work system 10, but multiple tape feeders 90 may be collectively exchanged in a location different from board work system 10 by utilizing housing rack 150. For example, in an area that is different from the work area for performing the mounting work and stores tape feeder 90, multiple tape feeders 90 may be collectively exchanged by utilizing housing rack 150.

### REFERENCE SIGNS LIST

10: board work system, 20: feeder housing (housing), 22: automatic exchange mounting device (mounting work machine) (feeder automatic exchange work machine), 24: manual exchange mounting device (mounting work machine) (feeder manual exchange work machine), 26: feeder exchange device (tape feeder exchange device), 30: conveyance device, 90: tape feeder, 120: tape feeder holding stand (mounting stand), 140: housing space, 150: housing rack (exchange mechanism), 160: upper housing space (housing space), 162: lower housing space (housing space)

1. A mounting work system comprising:
at least one feeder automatic exchange work machine configured to mount a component, which is supplied by a tape feeder mounted on a mounting stand, on a board conveyed by a conveyance device, the tape feeder mounted on the mounting stand being configured to be automatically exchanged by an operation of a tape feeder exchange device;
at least one feeder manual exchange work machine configured to mount a component, which is supplied by a tape feeder mounted on a mounting stand, on the board conveyed by a conveyance device, the tape feeder mounted on the mounting stand being configured to be manually exchanged by an operator; and
a housing formed with a housing space for housing at least one tape feeder, arranged in a conveyance direction of the conveyance devices, and disposed adjacent to the at least one feeder automatic exchange work machine.

2. The mounting work system according to claim 1,
wherein the at least one feeder manual exchange work machine is disposed adjacent to the at least one feeder automatic exchange work machine on a side opposite to the housing.

3. The mounting work system according to claim 1,
wherein each of the at least one feeder automatic exchange work machine has a housing space for housing a tape feeder by utilizing an entire width of a space formed below the mounting stand.

4. The mounting work system according to claim 3,
wherein multiple tape feeders in the housing space of at least one of the housing and the feeder automatic exchange work machine are collectively exchanged by using an exchange mechanism for exchanging a tape feeder.

5. The mounting work system according to claim 1,
wherein the housing formed with a housing space having multiple stages is provided.

6. A method for exchanging a tape feeder, the method comprising:
collectively exchanging multiple tape feeders housed in a housing space for housing a tape feeder by using an exchange mechanism for exchanging a tape feeder.
